(19) United States
(12) Patent Application Publication
(10) Pub. No.: US 2018/0336946 A1
(43) Pub. Date: Nov. 22, 2018

(54) MEMORY OPERATING METHOD AND MEMORY OPERATING DEVICE

(71) Applicant: MACRONIX INTERNATIONAL CO., LTD., Hsinchu (TW)

(72) Inventors: Yu-Hsuan Lin, Taichung City (TW); Chao-I Wu, Hsinchu City (TW); Dai-Ying Lee, Hsinchu County (TW)

(21) Appl. No.: 15/600,851

(22) Filed: May 22, 2017

(51) Int. Cl. G11C 13/00

(52) U.S. Cl. CPC G11C 13/0069; G11C 13/0026; G11C 13/0064; G11C 2013/0057; G11C 13/0028; G11C 2013/0042; G11C 13/0002; G11C 13/0004

(57) ABSTRACT

A memory operating method and a memory operating device are provided. The memory operating method includes the following steps. A first stepping loop is performed. A second stepping loop is performed. In the first stepping loop, a first control voltage applied to a first control line is increased from a first initial value to a first final value which is larger than the first initial value, and a second control voltage applied to a second control line is fixed at a second initial value. In the second stepping loop, the first control voltage applied to the first control line is fixed at a fixing value, and the second control voltage applied to the second control line is increased from an intermediate value to a second final value which is larger than the second initial value.

### TECHNICAL FIELD

The disclosure relates in general to an operating method and an operating device, and more particularly to a memory operating method and a memory operating device.

### BACKGROUND

Along with the development of memory technology, various memories are invented. Resistive Random-Access Memory (ReRAM) and Phase-Change Memory (PCM) are non-volatile random-access memories. The ReRAM is worked by changing the resistance across a dielectric solid-state material. The PCM is worked by changing the phase. In the ReRAM or the PCM, cells are required fine writing controllability to prevent over-writing issue. However, executing speed is limited if many steps are required.

### SUMMARY

The disclosure is directed to a memory operating method and a memory operating device. By performing a first stepping loop and a second stepping loop, the executing speed can be greatly improved.

According to one embodiment, a memory operating method is provided. The memory operating method includes the following steps. A first stepping loop is performed. A second stepping loop is performed. In the first stepping loop, a first control voltage applied to a first control line is increased from a first initial value to a first final value which is larger than the first initial value, and a second control voltage applied to a second control line is fixed at a second initial value. In the second stepping loop, the first control voltage applied to the first control line is fixed at a fixing value, and the second control voltage applied to the second control line is increased from an intermediate value to a second final value which is larger than the second initial value.

According to another embodiment, a memory operating device is provided. The memory operating device includes a first controller, a second controller and a processor. The first controller is for controlling a first control voltage applied to a first control line. The second controller is for controlling a second control voltage applied to a second control line. The processor is for performing a first stepping loop and a second stepping loop. In the first stepping loop, a first control voltage applied to a first control line is increased from a first initial value to a first final value which is larger than the first initial value, and a second control voltage applied to a second control line is fixed at a second initial value. In the second stepping loop, the first control voltage applied to the first control line is fixed at a fixing value, the second control voltage applied to the second control line is increased from an intermediate value to a second final value which is larger than the second initial value.

### BRIEF DESCRIPTION OF THE DRAWINGS

FIG. 1 shows a memory operating device for operating a memory.

FIGS. 2A and 2B show a flow chart of a memory operating method according to one embodiment.

FIG. 3 is a distribution diagram of the total number of shots.

FIG. 4 is a distribution diagram of the resistance according to the present embodiment.

FIGS. 5A and 5B show a flow chart of a memory operating method according to another embodiment.

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

### DETAILED DESCRIPTION

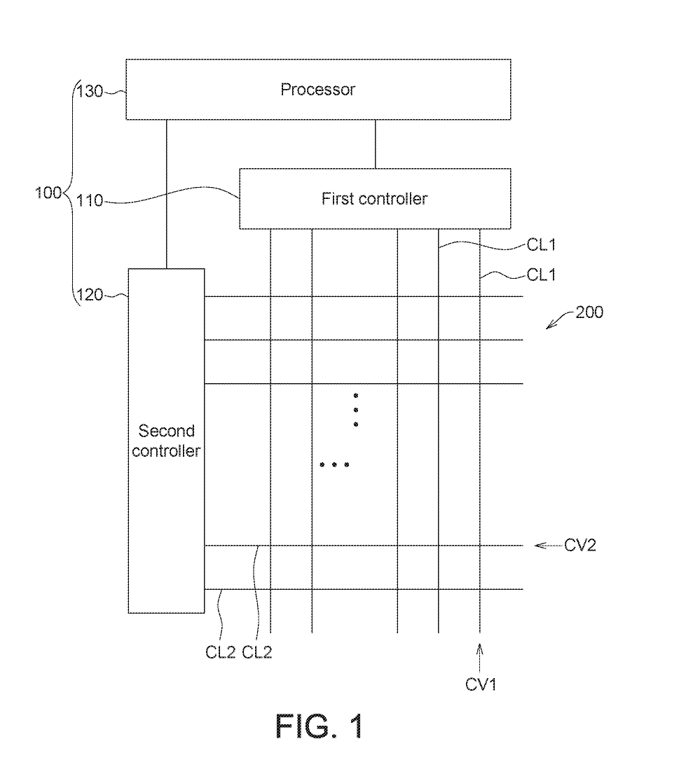

Please refer to FIG. 1, which shows a memory operating device 100 for operating a memory 200. The memory operating device 100 may be a computer, a processing equipment, a circuit board, a circuit, a chip or a storage device string a plurality of program codes. The memory 200 may be a Resistive Random-Access Memory (ReRAM) or a Phase-Change Memory (PCM). The memory 200 includes a plurality of first control lines CL1 and a plurality of second control lines CL2. In one embodiment, each of the first control lines CL1 may be a bit line or a source line, and each of the second control lines CL2 may be a word line. In another embodiment, each of the first control lines CL1 may be a word line, and each of the second control lines CL2 may be a bits line or a source line. The memory operating device 100 includes a first controller 110, a second controller 120 and a processor 130. The first controller 110 is used for controlling the first control lines CL1, and the second controller 120 is used for controlling the second control lines CL2.

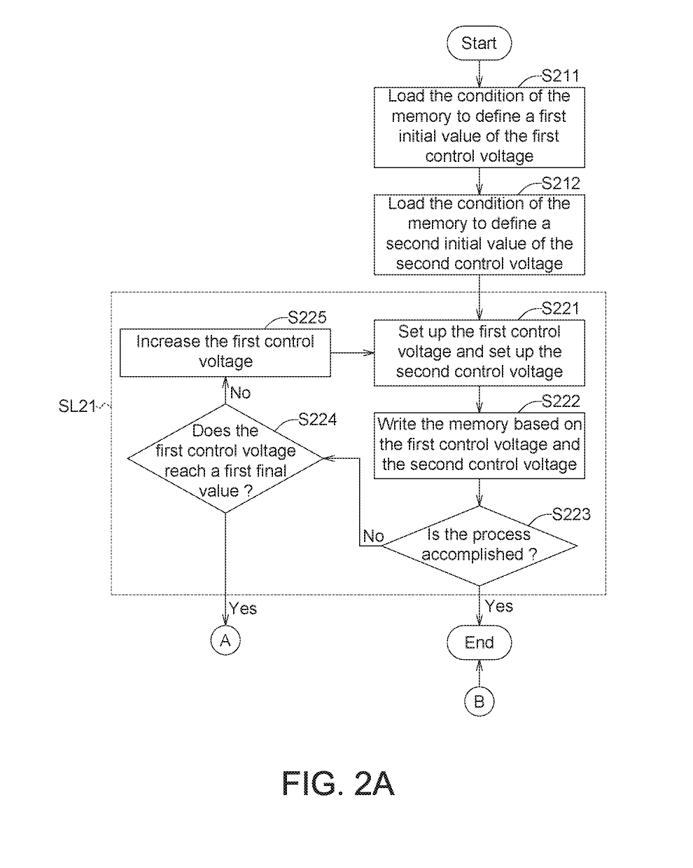

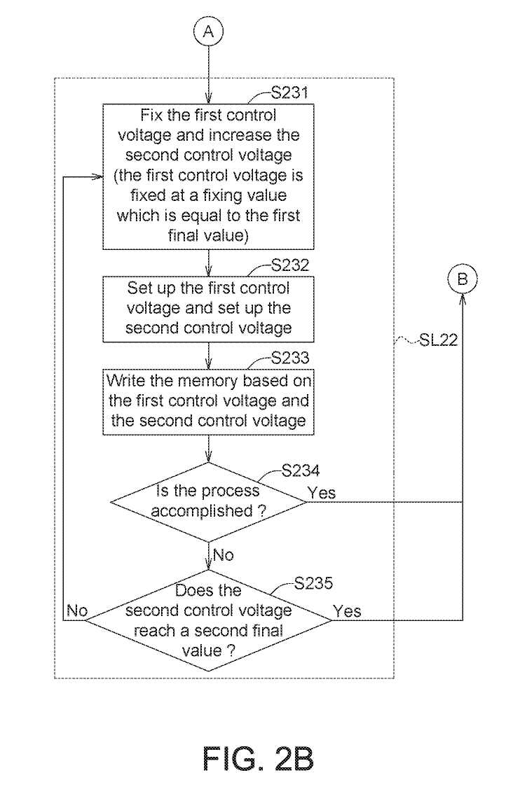

Please refer to FIGS. 2A and 2B, which show a flow chart of a memory operating method according to one embodiment. The memory operating method is used for performing a FORM process, a SET process or a RESET process. For those processes, the executing speed is needed to be improved in various applications. In this embodiment, the memory operating method includes two stepping loops, such as a first stepping loop SL21 and a second stepping loop SL22.

In the first stepping loop SL21, a first control voltage CV1 applied to the first control line CL1 is gradually increased, and a second control voltage CV2 applied to the second control line CL2 is fixed.

In the second stepping loop SL22, the first control voltage CV1 applied to the first control line CL1 is fixed, and the second control voltage CV2 applied to the second control line CL2 is gradually increased.

The second stepping loop SL22 is performed after the first stepping loop SL21. Once the first stepping loop SL21 is finished and the process proceeds to the second stepping loop SL22, the process does not back to the first stepping loop SL21. By performing the first stepping loop SL21 and the second stepping loop SL22, the executing speed is improved.

In detail, the memory operating method includes the following steps. In step S211, the processor 130 loads the condition of the memory 200 to define a first initial value of the first control voltage CV1. In step S212, the processor 130 loads the condition of the memory 200 to define a second initial value of the second control voltage CV2. The first initial value is a proper value that the writing (forming) current can go through the first control line CL1 of the memory 200 without over-writing. Usually, the first initial value is close to but less than a switch point on the dynamic resistance plot of the memory 200. For example, the first initial value may be 2 V. Similarly, the second initial value is a proper value that the writing (forming) current can go through the second control line CL2 of the memory 200 without over-writing. Usually, the second initial value is close to but less than a switch point on the dynamic resistance plot of the memory 200. For example, the second initial value may be 2 V.

Referring to table I, during the first stepping loop SL21 and the second stepping loop SL22, the first control voltage CV1 and the second control voltage CV2 are set up according to the table I.

TABLE I

| | First control voltage CV1 | Second control voltage CV2 |
|---|---|---|
| First | first initial value to first final | second initial value |
| stepping | value | |
| loop SL21 | | |
| Second | fixing value | intermediate value to |
| stepping | | second final value |
| loop SL22 | *The fixing value is equal to | *The intermediate value is |
| | the first final value. | larger than the second initial |
| | | value. |

Next, in step S221, the first controller 110 sets up the first control voltage CV1 and the second controller 120 sets up the second control voltage CV2.

In step S222, the memory 200 is written based on the first control voltage CV1 and the second control voltage CV2 for performing the FORM process, the SET process or the RESET process.

Then, in step S223, the processor 130 determines whether the FORM process, the SET process or the RESET process is accomplished or not. If the FORM process, the SET process or the RESET process is accomplished, then the method is terminated; if the FORM process, the SET process or the RESET process is not accomplished, then the process proceeds to step S224.

In step S224, the processor 130 determines whether the first control voltage CV1 reaches a first final value or not. For example, the first final value may be 5V. If the first control voltage CV1 reaches the first final value, then the process proceeds to step S231; if the first control voltage CV1 does not reach the first final value, then the process proceeds to step S225.

In step S225, the first control voltage CV1 is increased by a predetermined value, such as 1 V. Then, the method backs to the step S221 and the step S222 for writing the memory 200 again based on the increased first control voltage CV1. The first stepping loop SL21 is repeatedly performed until the FORM process, the SET process or the RESET process is accomplished or the first control voltage CV1 reaches the first final value.

In step S231, the first controller 110 fixes the first control voltage CV1 applied to the first control line CL1 at the fixing value and the second controller 120 increases the second control voltage CV2 applied to the second control line CL2. The second control voltage CV2 is increased from the intermediate value. In this embodiment, the fixing value is equal to the first final value. For example, the first final value is 5V and the fixing value is 5V. The intermediate value is larger than the second initial value. For example, the second initial value is 2V and the intermediate value is 3V.

In step S232, the first controller 110 sets up the first control voltage CV1 and the second controller 120 sets up the second control voltage CV2.

In step S233, the memory 200 is written based on the first control voltage CV1 and the second control voltage CV2 for performing the FORM process, the SET process or the RESET process.

Then, in step S234, the processor 130 determines whether the FORM process, the SET process or the RESET process is accomplished or not. If the FORM process, the SET process or the RESET process is accomplished, then the method is terminated; if the FORM process, the SET process or the RESET process is not accomplished, then the method proceeds to step S235.

In step S235, the processor 130 determines whether the second control voltage CV2 reaches the second final value or not. For example, the second final value may be 5V. If the second control voltage reaches the second final value, then the method is terminated; if the second control voltage does not reach the second final value, then the method backs to the step S231. If the method backs to the steps S231 and the step S232, the second controller 120 increases the second control voltage CV2 again and the memory 200 is written again based on the increased second control voltage CV2.

The second stepping loop SL22 is repeatedly performed until the FORM process, the SET process or the RESET process is accomplished or the second control voltage CV2 reaches the second final value.

That is to say, in the first stepping loop SL21, the first control voltage CV1 applied to the first control line CL1 is increased from the first initial value to the first final value which is larger than the first initial value, and the second control voltage CV2 applied to the second control line CL2 is fixed at the second initial value. In the second stepping loop SL22, the first control voltage CV1 applied to the first control line CL1 is fixed at the fixing value which is equal to the first final value, and the second control voltage CV2 applied to the second control line CL2 is increased from the intermediate value, which is larger than the second initial value, to the second final value, which is larger than the intermediate value.

Please refer to the table II, which show an example for performing the FORM process. In this example, the memory 200 is the ReRAM including a TiN layer, a WOx layer and a TiN layer. The first control line CL1 is the bit line (or the source line), and the second control line CL2 is the word line. In the first stepping loop SL21, the voltage of the bit line is increased from 2V to 4V and the voltage of the word line is fixed at 2V. In the second stepping loop SL22, the voltage of the bit line is fixed at 4V and the voltage of the word line is increased from 3V to 4V. In this example, the total number of shots is 5. Comparing to the conventional FORM process, the total number of shots is 9. Therefore, the executing speed in this example is greatly improved.

TABLE II

| | Voltage of the word line | Voltage of the bit line |
|---|---|---|
| | (Second control voltage | (First control voltage |
| | CV2) | CV1) |
| First stepping loop | 2 V | 2 V, 3 V, 4 V |
| SL21 | | |
| Second stepping loop | 3 V, 4 V | 4 V |
| SL22 | | |

| | |
|---|---|
| Total number of shots | 5 shots |

Please refer to the table III, which show an example for performing the SET process. In this example, the memory 200 is the ReRAM including a TiN layer, a WOx layer and a TiN layer. The first control line CL1 is the word line, and the second control line CL2 is the bit line (or the source line). In the first stepping loop SL21, the voltage of the word line is increased from 2V to 5V and the voltage of the bit line is fixed at 2V. In the second stepping loop SL22, the voltage of the word line is fixed at 5V and the voltage of the bit line is increased from 3V to 5V. In this example, the total number of shots is 7. Comparing to the conventional SET process, the total number of shots is 16. Therefore, the executing speed in this example is greatly improved.

TABLE III

| | Voltage of the word line | Voltage of the bit line |
|---|---|---|
| | (Second control voltage | (First control voltage |
| | CV2) | CV1) |
| First stepping loop | 2 V, 3 V, 4 V, 5 V | 2 V |
| SL21 | | |
| Second stepping loop | 5 V | 3 V, 4 V, 5 V |
| SL22 | | |

| | |
|---|---|
| Total number of shots | 7 shots |

Please refer to the table IV, which show an example for performing the RESET process. In this example, the memory 200 is the ReRAM including a TiN layer, a WOx layer and a TiN layer. The first control line CL1 is the word line, and the second control line CL2 is the bit line (or the source line). In the first stepping loop SL21, the voltage of the word line is increased from 2V to 5V and the voltage of the bit line is fixed at 2V. In the second stepping loop SL22, the voltage of the word line is fixed at 5V and the voltage of the bit line is increased from 3V to 5V. In this example, the total number of shots is 7. Comparing to the conventional SET process, the total number of shots is 16. Therefore, the executing speed in this example is greatly improved.

TABLE IV

| | Word line (Second | Bit line (First control |
|---|---|---|
| | control voltage CV2) | voltage CV1) |
| First stepping loop SL21 | 2 V, 3 V, 4 V, 5 V | 2 V |
| Second stepping loop | 5 V | 3 V, 4 V, 5 V |
| SL22 | | |

| | |
|---|---|
| Total number of shots | 7 shots |

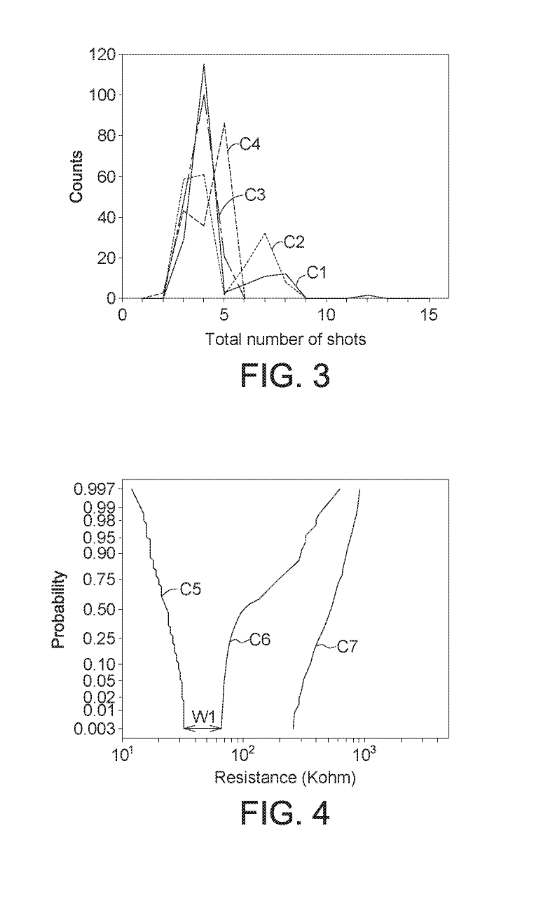

Please refer FIG. 3, which is a distribution diagram of the total number of shots. In FIG. 3, four curves C1, C2, C3 and C4 are shown. The curve C1 illustrates a distribution of the total number of shots according to the conventional SET process, the curve C2 illustrates a distribution of the total number of shots according to the conventional RESET process, the curve C3 illustrates a distribution of the total number of shots according to the present disclosed SET process, and the curve C4 illustrates a distribution of the total number of shots according to the present disclosed RESET process. Referring to the curves C1, the total numbers of shots in some of the conventional SET processes are larger than 6. Referring to the curve C3, the total numbers of shots in all of the present disclosed SET processes are less than 6. That is to say, the executing speed of the present disclosed SET processes is improved.

Referring to the curve C2, the total numbers of shots in some of the conventional RESET processes are larger than 6. Referring to the curve C4, the total numbers of shots in all of the present disclosed RESET processes are less than 6. That is to say, the executing speed of the present disclosed SET processes is improved.

Please refer to FIG. 4, which is a distribution diagram of the resistance according to the present embodiment. In FIG. 4, three curves C5, C6 and C7 are shown. The curve C5 illustrates a distribution of the resistance of the memory 200 after performing the present disclosed SET process, the curve C6 illustrates a distribution of the resistance of the memory 200 after performing the present disclosed RESET process, and the curve C7 illustrates a distribution of the resistance of the memory 200 after performing the present disclosed FORM process. A window W1 is between the curve C5 and the curve C6, such that the SET state and the RESET state can be clearly distinguished. That is to say, even if the total number of shuts is reduced, the results of the SET process and the result of the RESET process are still well.

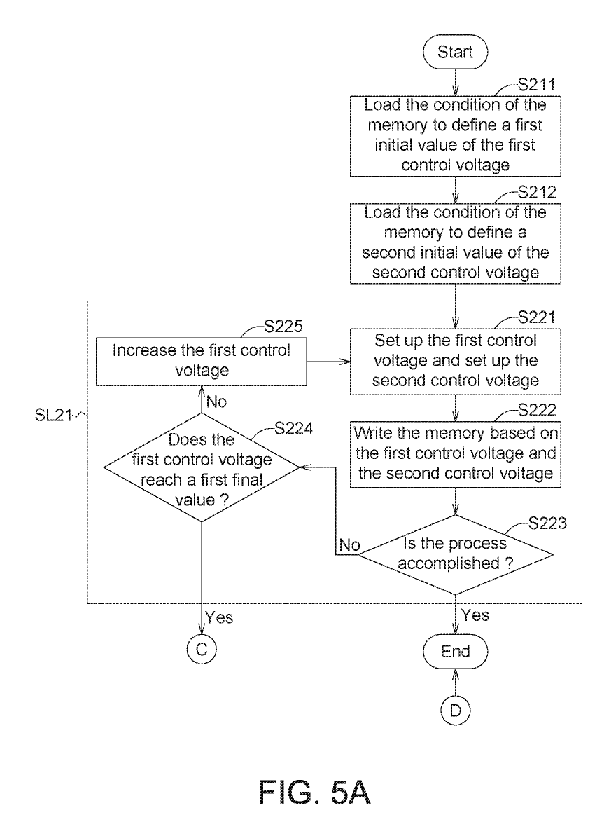

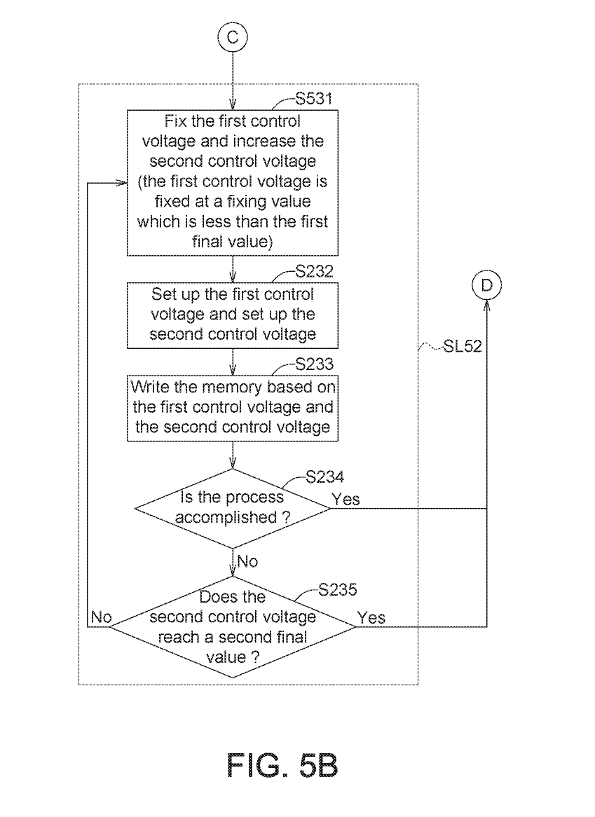

Please refer to FIGS. 5A and 5B, which show a flow chart of a memory operating method according to another embodiment. Referring to table V, during the first stepping loop SL51 and the second stepping loop SL52, the first control voltage CV1 and the second control voltage CV2 are set up according to the table V.

TABLE V

| | First control voltage CV1 | Second control voltage CV2 |
|---|---|---|
| First | first initial value to first final | second initial value |
| stepping | value | |
| loop SL51 | | |
| Second | fixing value | intermediate value to |
| stepping | | second final value |
| loop SL52 | *The fixing value is less than | *The intermediate value is |
| | the first final value. | larger than the second initial |
| | | value. |

In this embodiment, the first stepping loop SL51 is similar to the first stepping loop SL21, and the similarities will not repeated here. In the step S531 of the second stepping loop SL52, the fixing value is less than the first final value. The fixing value may be calculated according to the following equation (1).

FX=FN−Δ (1)

FX is the fixing value, FN is the first final value, and A ranges from 0 to the first final value.

Or, in another embodiment, a ratio of the fixing value to the first final value is larger than 0.8. Or, in another embodiment, a difference between the fixing value and the first final value is larger than 0.1 V. For example, the first final value is 5V and the fixing value is 4.5 V.

Because the first control voltage CV1 in the second stepping loop SL52 is kept at the fixing value which is less than the first final value, the over-writing issue can be prevented from in some case.

That is to say, in the first stepping loop SL51, the first control voltage CV1 applied to the first control line CL1 is increased from the first initial value to the first final value which is larger than the first initial value. The second control voltage CV2 applied to the second control line CL2 is fixed at the second initial value. In the second stepping loop SL52, the first control voltage CV1 applied to the first control line CL1 is fixed at the fixing value which is less than the first final value, and the second control voltage CV2 applied to the second control line CL2 is increased from the intermediate value, which is larger than the second initial value, to the second final value, which is larger than the intermediate value.

According to the embodiments disclosed above, the executing speed can be greatly improved by performing the first stepping loop SL21, SL51 and the second stepping loop SL22, SL52.

It will be apparent to those skilled in the art that various modifications and variations can be made to the disclosed embodiments. It is intended that the specification and examples be considered as exemplary only, with a true scope of the disclosure being indicated by the following claims and their equivalents.

What is claimed is:

1. A memory operating method, comprising:
performing a first stepping loop, wherein in the first stepping loop, a first control voltage applied to a first control line is increased from a first initial value to a first final value which is larger than the first initial value, and a second control voltage applied to a second control line is fixed at a second initial value; and
performing a second stepping loop, wherein in the second stepping loop, the first control voltage applied to the first control line is fixed at a fixing value, and the second control voltage applied to the second control line is increased from an intermediate value to a second final value which is larger than the second initial value.

2. The memory operating method according to claim 1, wherein the intermediate value is larger than the second initial value.

3. The memory operating method according to claim 1, wherein the fixing value is equal to the first final value.

4. The memory operating method according to claim 1, wherein the fixing value is less than the first final value.

5. The memory operating method according to claim 4, wherein a ratio of the fixing value to the first final value is larger than 0.8.

6. The memory operating method according to claim 4, wherein a difference between the fixing value and the first final value is larger than 0.1 V.

7. The memory operating method according to claim 1, wherein the second stepping loop is performed after the first stepping loop.

8. The memory operating method according to claim 1, wherein the first control line is a bit line or a source line, and the second control line is a word line.

9. The memory operating method according to claim 1, wherein the first control line is a word line, and the second control line is a bit line or a source line.

10. The memory operating method according to claim 1, wherein the first initial value is larger than 1V and the second initial value is larger than 1V.

11. A memory operating device, comprising:
a first controller for controlling a first control voltage applied to a first control line;
a second controller for controlling a second control voltage applied to a second control line; and
a processor for performing a first stepping loop and a second stepping loop, wherein
in the first stepping loop, a first control voltage applied to a first control line is increased from a first initial value to a first final value which is larger than the first initial value, and a second control voltage applied to a second control line is fixed at a second initial value; and
in the second stepping loop, the first control voltage applied to the first control line is fixed at a fixing value, the second control voltage applied to the second control line is increased from an intermediate value to a second final value which is larger than the second initial value.

12. The memory operating device according to claim 11, wherein the intermediate value is larger than the second initial value.

13. The memory operating device according to claim 11, wherein the fixing value is equal to the first final value.

14. The memory operating device according to claim 11, wherein the fixing value is less than the first final value.

15. The memory operating device according to claim 14, wherein a ratio of the fixing value to the first final value is larger than 0.8.

16. The memory operating device according to claim 14, wherein a difference between the fixing value and the first final value is larger than 0.1 V.

17. The memory operating device according to claim 11, wherein the second stepping loop is performed after the first stepping loop.

18. The memory operating device according to claim 11, wherein the first control line is a bit line or a source line, and the second control line is a word line.

19. The memory operating device according to claim 11, wherein the first control line is a word line, and the second control line is a bit line or a source line.

20. The memory operating device according to claim 11, wherein the first initial value is larger than 1V and the second initial value is larger than 1V.
